(19) United States
(12) Patent Application Publication
(10) Pub. No.: US 2025/0385097 A1
(43) Pub. Date: Dec. 18, 2025

(54) Dynamic Parameter Adjustment in Atomic Layer Etching for High Aspect Ratio Structure Formation

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/745,269

(22) Filed: Jun. 17, 2024

(51) Int. Cl. H01L 21/3065; H01J 37/32

(52) U.S. Cl. CPC H01L 21/30655; H01J 37/32082; H01J 37/32926; H01J 2237/334

(57) ABSTRACT

Disclosed herein is a method for high aspect ratio (HAR) structure formation in semiconductor manufacturing using atomic layer etching (ALE). The method involves dynamically adjusting process parameters such as surface modification step duration and sputtering step bias level in relation to the ALE cycle count. This adjustment can be guided by a pre-established model or empirical data from prior tests, enhancing precision and efficiency in HAR structure etching.

### BACKGROUND OF THE INVENTION

### 1. Field of the Invention

The present invention pertains to the field of semiconductor manufacturing, more specifically to methods and systems for atomic layer etching (ALE) utilized in the formation of high aspect ratio (HAR) structures. The invention focuses on the enhancement of ALE processes through the dynamic adjustment of various process parameters, catering to the evolving requirements of precision etching in semiconductor fabrication.

### 2. Description of the Prior Art

Reactive ion etching (RIE) is a predominant technology in semiconductor manufacturing. In RIE, diverse species including neutrals, radicals, and ions concurrently influence the etching process. A key characteristic of RIE is the synergistic interaction between ion and neutral fluxes, which significantly enhances the etching rate. This synergistic effect was first described by Coburn and Winters in “Ion-and electron-assisted gas-surface chemistry-an important effect in plasma etching,” published in J. Appl. Phys., vol. 50, pages 3189-3196 (1979). They reported increased silicon etching rates when using an argon ion beam, a XeF2 neutral beam, and their combination. Further, Gottscho et al., in “Microscopic uniformity in plasma etching” (J. Vac. Sci. Technol., B10, pages 2133-2147, 1992), developed a model to quantify this synergy for the etching rate ER:

$$ER = \frac{υ {E}_{i} {J}_{i}}{1 + ( υ {E}_{i} {J}_{i} ) / ( {υ}_{n} {sJ}_{n} )} ,$$

where υ represents the volume removed per unit bombardment energy for a saturated surface (cm³/eV), Eᵢ the ion energy (eV), Jᵢ the ion flux to the surface (cm²/s), υₙ the volume removed per reacting neutral (cm³), Jₙ the neutral flux to the surface and s the sticking probability of the neutral species on the bare surface.

Achieving effective RIE necessitates the presence of both ion and neutral fluxes to exploit the synergy identified by Coburn and Winters. However, it is increasingly complex in modern etching apparatus to balance these fluxes, particularly for etching high aspect ratio structures with dimensions shrinking to nanometer scale. Uniform results across 300 mm wafers and consistent repeatability in production pose additional challenges.

Over the past several decades, advancements in etching apparatus features have been made to enhance uniformity. For instance, the evolution of plasma sources from a single coil (U.S. Pat. No. 4,948,458 to Ogle) to multiple coils (U.S. Pat. No. 6,164,241 to Chen et al.) has been notable, either in the form of inductively coupled plasma (ICP) or transformer coupled plasma (TCP). Additionally, gas injection techniques have improved, incorporating multiple injection points to ensure a uniform plasma within the vacuum reactor, as described in U.S. Pat. Nos. 8,231,799 to Bera et al. and 10,825,659 to Treadwell. Further enhancements include optimizing the electrostatic chuck (ESC) to feature multiple zones with independently adjustable temperatures (U.S. Pat. Nos. 9,713,200 to Pease and 10,056,225 to Gaff et al.).

A radio frequency (RF) power generator, coupled to the ESC, provides a bias for the ions in the plasma in addition to the plasma sheath. This coupling, facilitated through a blocking capacitor, helps establish a stable plasma sheath by preventing electron flow to the ground, as detailed in U.S. Pat. No. 5,302,240 to Hori et al. Moreover, various pulsing schemes for RF power generators have been implemented to improve ion energy and angular momentum distribution, thereby maximizing the synergetic effects between ions and neutrals, as described in U.S. Pat. Nos. 8,264,154 to Banner et al. and 10,121,639 to Kanarik. RF power generators with tailored waveforms, as discussed by Wang et al. in “Experimental demonstration of multifrequency impedance matching for tailored voltage waveform plasmas” (J. Vac. Sci. Technol. A37, 021303, pages 1-11, 2019), have also been employed to precisely control ion energy.

Additionally, gases can be pulsed in a cyclic process to enhance performance, as disclosed in U.S. Pat. No. 10,121,639 to Kanarik. This cyclic approach segments the RIE process into steps, each optimized with a different set of process gases.

Despite these improvements, achieving the required uniformity across a 300 mm wafer for critical dimension (CD), loading, and profile remains a significant challenge, often entailing considerable expense.

ALE has been developed to address the limitations of RIE. ALE apparatus has evolved from the RIE apparatus with less stringent requirements for achieving uniformity on a 300 mm wafer. However, ALE has unique requirements due to the nature of its process steps.

An overview of ALE technology is presented by Karanik et al. in “Overview of atomic layer etching in the semiconductor industry” (J. Vac. Sci. Technol. A33, pages 020802 1-14, 2015), and further discussed in a book by Lill, “Atomic layer processing: semiconductor dry etching technology” (Wiley-VCH GmbH, Boschstr. 12, 69469 Weinheim, Germany, 2021). ALE facilitates the controlled removal of material layers with atomic-level precision and is characterized as an etching technique using sequential self-limiting reactions. The basic ALE process includes two steps: surface modification and sputtering for removing modified surface. The modification creates a thin reactive layer with a defined thickness, which is easier to remove than the unmodified material. The sputtering step eliminates this modified layer while preserving the underlying substrate, thus resetting the surface for subsequent cycles. The material removal is quantified over multiple cycles and can be achieved using thermal energy by raising the wafer's temperature or kinetic energy from ions typically derived from inert gases. The isotropic process using thermal energy to remove modified layers is described in U.S. Pat. No. 10,208,383 to George et al. When utilizing energetic ions, the removal is conducted via a sputtering process.

The anisotropic ALE process, which is the focus of the present invention, has been employed for etching various materials, demonstrating the technology's versatility:
Si and Ge as described in U.S. Pat. No. 10,727,073 to Tan et al.,
SiO2 as described in U.S. Pat. No. 9,620,382 to Oehrlein et al.,
C as described in U.S. Pat. Pub. Nos. 2017/0316935 and 2022/0216050 by Tan et al.,
W as described in U.S. Pat. Pub. No. 2020/0286743 from Lai et al and U.S. Pat. No. 10,096,487 to Yang et al,
Co as described in U.S. Pat. No. 10,096,487 to Yang et al,
Ru as described in U.S. Pat. Pub. No. 2022/0199422 by Yang et al.,
Other refractory metals and materials with high surface binding energy as described in U.S. Pat. No. 11,450,513 to Yang et al.,
Cu as described in WO Pat. Pub. No. 2022/046429 by Yang et al.,
GaN and other III-V materials as described in U.S. Pat. No. 10,056,264 to Yang et al.,
MRAM as described in U.S. Pat. Nos. 10,749,103 to Tan et al.,
EUV patterning as described in U.S. Pat. 9,922,839 to Wise et al., and
Surface smoothing of various materials as described in U.S. Pat. No. 10,304,659 to Karanik et al.

It should also be noted that a deposition component in the ALE steps or an independent deposition step is often introduced in the ALE process to enhance its performance, especially for controlling the profile of structures being etched. For example, selective deposition on a carbon-containing material is applied to improve ALE performance as described in U.S. Pat. Pub. No. 2017/0316935 by Tan et al. Additionally, as disclosed in U.S. Pat. No. 9,805,941 to Karanik et al., atomic layer deposition (ALD) and ALE are conducted from a single plasma chamber. This method involves sequentially alternating between ALE and ALD processes to prevent feature degradation during etching, improve selectivity, and encapsulate sensitive layers of a semiconductor substrate.

The distinct chemistry, speciation, and plasma energy composition involved in the surface modification and sputtering steps enhance the process by enabling more controlled ion, electron, and neutral species fluxes, thereby widening the process window. This separation facilitates self-limiting reactions, crucial for maintaining the ideality of the etching process—characterized by uniformity, smoothness, and selectivity. Karanik et al. in “Predicting synergy in atomic layer etching” (J. Vac. Sci. Technol. A35, pages 05C302 1-7, 2017) defined ALE synergy as:

$${ALE}_{synergy} S ( \% ) = \frac{EPC - ( α + β )}{EPC} \times 100 \%$$

EPC is “etch per cycle” representing the total thickness of material removed in one cycle, typically averaged over many cycles. The values of “α” and “β” are (undesirable) contributions from the surface modification step and the sputtering step, respectively. Ideally, synergy will approach 100% with no etching from either step alone. In practice, RIE in the surface modification step are nonzero because of presence of ions in the plasma which generates neutrals to modify the surface. In the sputtering step, physical sputtering of underlying unmodified layer is also nonzero.

It is desirable for the plasma in the surface modification step of the ALE process to be free from ion bombardment. However, the unintended introduction of RIE components during this step presents a persistent challenge. This issue stems from the difficulty in completely preventing ion bombardment of the substrate surface, compromising the ideality of the ALE processes. Modern ALE methodologies struggle to effectively eliminate these RIE components, leading to suboptimal etching outcomes, particularly as device geometries become more complex and smaller in scale. The presence of RIE components in ALE processes can result in non-uniform layer removal and undesirable etching profiles, which are especially problematic in advanced device manufacturing where even minor deviations can significantly impact device performance and yield.

One solution to this problem, as disclosed in U.S. Pat. No. 9,362,131 to Agarwal et al., involves using an electron beam source. During the passivation step (surface modification step), a remote plasma source supplies passivation species to the main process chamber while keeping ion energy below the etching threshold. During the etching operations, the flow from the remote plasma source is stopped, and the ion energy is raised above the etch threshold. This approach introduces an additional remote source. It complicates the apparatus and may increase the cost of the process.

In addition to tackling challenges related to achieving higher synergy in ALE, efforts have been made to enhance the speed of the ALE process. For instance, high-energy ions, more than 150 eV, are used to remove the modified surface layer as disclosed in U.S. Pat. No. 10,763,083 to Yang et al. Furthermore, pulsing has been applied to an RF power generator coupled to an ESC to provide a bias for the ions in the plasma. In another development disclosed in WO Pat. Pub. No. 2023/183129, the sputtering time in the sputtering step has been reduced to a range between 10 ms and 600 ms.

Another approach to increasing the speed of the ALE process involves relaxing the requirements for self-limiting reactions, as disclosed in TW Pat. No. 1757334 to Cottle et al. While this method accelerates the ALE process, it may reduce the synergy factor, thereby degrading the performance of ALE.

The speed challenge becomes even more significant when dealing with HAR structures. In the realm of semiconductor manufacturing today, the creation of the HAR structures is a critical and challenging aspect, especially as device miniaturization continues to advance. Traditional etching methods face difficulties in maintaining etching fidelity and uniformity as the aspect ratios of these structures increase as disclosed in U.S. Pat. No. 7,329,616 to Tsuchiya, U.S. Pat. No. 7,682,986 to Chi et al. and U.S. Pat. No. 8,901,004 to Kamp et al. These challenges are accentuated in ALE processes, where precise control over etching parameters is essential to achieve the desired structure and surface quality. However, as the etch front progresses deeper into the substrate, conventional ALE processes also encounter issues such as reduced etching rate, profile distortion, and decreased selectivity, primarily due to factors like ion momentum angular distribution and the varying distance between the etch front and the surface of a substrate being etched. Existing methods in ALE processes often utilize fixed parameters throughout the etching cycles, which can be suboptimal for the HAR structure formation. This approach does not account for the changes in etching dynamics as the process progresses, leading to inefficiencies and potential compromises in the quality of the etched structures.

Therefore, there exists a need for an improved ALE method that can dynamically adapt its process parameters, such as the duration at the surface modification step and the bias level at the sputtering step, in response to the changing requirements of the etching process. Such advancements would significantly benefit the semiconductor manufacturing industry by enabling more precise and efficient formation of HAR structures, thus meeting the demands of modern electronic device fabrication.

### SUMMARY

The present invention discloses innovative methods in the field of semiconductor manufacturing, particularly focusing on HAR structure formation by utilizing of ALE. The core innovation lies in the progressive alteration of process parameters specified by a recipe during the ALE process, enhancing the precision and efficiency of etching.

In some embodiments, the invention involves dynamically adjusting the duration of the surface modification step and the bias level during the sputtering step in correlation with the ALE cycle count. This adjustment ensures that the etching process remains optimal as the etch front progresses, thereby maintaining high fidelity in the formation of HAR structures.

In certain implementations, the duration of the surface modification step and the bias level for the sputtering step are determined based on a pre-established model. This model considers various chamber parameters and process requirements, offering a calculated approach to the dynamic adjustment of the ALE process.

Alternatively, in some embodiments, the parameters are set based on the results of prior tests, such as those conducted during the ALE process recipe development phase. These tests, including but not limited to design of experiments (DOE), provide empirical data that guide the optimization of the process parameters for each specific ALE cycle.

Furthermore, the invention encompasses variations in the adjustment of other process parameters as well, such as the composition of gases, RF power levels and frequencies, chamber pressure, and chuck temperature. Each of these parameters can be varied progressively in relation to the ALE cycle count, thereby offering a comprehensive approach to optimizing the ALE process for HAR structure formation.

The embodiments detailed in this invention highlight the adaptability and sophistication of the ALE process, making it particularly suitable for advanced semiconductor manufacturing where precision and control are paramount.

### BRIEF DESCRIPTIONS OF DRAWINGS

In order to provide enhanced clarity, the following description references the accompanying drawings:

FIG. 1 illustrates an exemplary process system for the ALE process.

FIG. 2A depicts schematically a method for HAR structure formation by progressively increasing the surface modification step duration as the ALE cycle count is increased.

FIG. 2B showcases schematically the method for the HAR structure formation by increasing further the bias level as the ALE cycle count is increased.

FIG. 3 presents a flowchart of the ALE process in accordance with an embodiment.

### DETAILED DESCRIPTIONS

To ensure comprehensive understanding, this section delves into detailed embodiments of the present invention. Although certain specifics are provided for clarity, modifications and variations that align with the subsequent claims are deemed appropriate. Conventional methods and components are highlighted to underscore the distinct features of the invention.

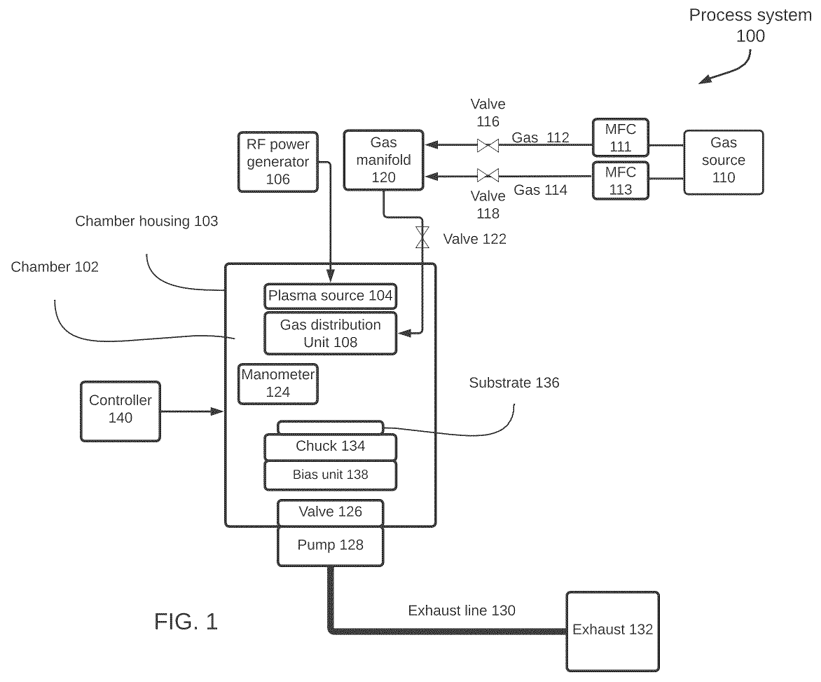

FIG. 1 illustrates an exemplary ALE process system, designated as 100. This system includes a chamber, referred to as 102. The functions within this chamber are orchestrated by a controller, denoted as 140. The chamber (102) is enclosed within a chamber housing, labeled 103, establishing a vacuum environment suitable for plasma processing. This housing (103) may be fabricated from materials such as aluminum or quartz, with the aluminum interior surface possibly undergoing specific treatments to enhance durability against the plasma environment. For example, this surface may be anodized or coated with an yttrium oxide layer.

Mounted atop the chamber housing (103) is a window (not depicted in FIG. 1), which hermetically seals the chamber (102). Depending on the embodiment, this window may be comprised of quartz or ceramic materials. Its interior surface can be coated with a plasma-resistant material, such as yttrium oxide. Situated above the window is a plasma source, identified as 104. The plasma source (104) may adopt various configurations, including but not limited to an ICP source or a TCP source.

The plasma source (104) is operationally connected to an RF power generator (106) via a resonator (not illustrated in FIG. 1). The RF power generator (106) can generate RF power at single or multiple frequencies, which may include but are not limited to 100 kHz, 200 kHz, 400 kHz, 2 MHz, 13.56 MHz, 27 MHz, 40 MHz, and 60 MHz. The resonator ensures the impedance output of the RF power generator (106) is matched with the plasma load of the chamber (102), accounting for the characteristics of transmission lines.

A gas distribution unit, referred to as 108, interfaces with a gas source, marked as 110. This gas source (110) supplies a first process gas (112) and a second process gas (114) to a gas manifold (120). These process gases are regulated by Mass Flow Controllers (MFC) 111 and 113, respectively. Valves 116 and 118 provide additional switching mechanisms for the first and second process gases, respectively. The manifold (120) connects to the gas distribution unit (108) through an aperture in the window, maintaining a hermetic seal essential for the chamber's (102) vacuum integrity. Another valve (optional), marked as 122, controls the entry of the process gas into the chamber (102).

The gas source (110) may encompass various gas delivery mechanisms, such as a gasbox. Depending on the specific design, the gas distribution unit (108) may be designed as either an injector or a showerhead. In some designs, the window is integrated with the gas distribution unit (108), serving both as a showerhead and as a seal for the chamber (102).

Additionally, the chamber (102) incorporates a chuck, designated as 134, which acts as a support structure for a substrate (136). The chuck (134) may be designed in various forms, including, but not limited to, an electrostatic chuck (ESC) or a vacuum chuck. The chamber (102) also includes a pump (128) and an associated valve (126). The pump (128) is responsible for removing residual gases and reaction byproducts. The operation of valve (126), in conjunction with the pump's (128) capacity, regulates the removal rate of these gases and byproducts. The controller (140) utilizes data from a manometer (124) to stabilize the chamber pressure by adjusting the valve (126).

The disclosed ALE process system is particularly effective for HAR structure formation and encompasses multiple ALE cycles. Each cycle includes a surface modification step to alter the surface of the substrate (136). For instance, in silicon etching, chlorine gas is utilized as the first process gas to modify the silicon surface, forming silicon-chlorine bonds. This modification weakens the bonding strength between adjacent silicon atoms. Subsequently, this surface modification step is followed by a sputtering step employing ions to remove the modified layer. Inert gases such as argon, helium, and xenon are suitable for this purpose. The chuck (134) connects to a bias unit (138) to establish an electrical bias. This bias may be generated using a tailored waveform generator or, alternatively, through an RF power generator linked to the chuck (134) via a resonator.

In certain embodiments tailored for HAR structure formation, a deposition step may be integrated between selected successive ALE cycles. This step aims to deposit a protective layer on the sidewalls of the HAR structures, mitigating profile distortion attributable to the lateral movement of ions, which is a consequence of the angular distribution of ion momentum.

Upon receiving the RF power, the plasma source (104) generates a plasma within the chamber (102). This plasma comprises electrons, neutrals, and ions. The neutrals diffuse towards the substrate's surface and the etch front, facilitating the surface modification step. The interaction of these neutrals with the substrate's surface atoms completes the surface modification process. The duration necessary for sufficient neutrals to reach the surface depends on various factors, including neutral density, chamber temperature, the gap between the plasma source (104) and the chuck (134), and the distance from the etch front to the substrate's surface. Given that the etch front is continually advancing during the ALE process, it is advantageous to adjust the duration of the surface modification step accordingly. This adjustment ensures optimal surface modification within the minimal time necessary for the ALE process.

In some implementations, the controller (140) progressively increases the duration of the surface modification step. A digital counter within the controller may tally the number of ALE cycles, and this count helps determine the appropriate duration for the surface modification step. Alternatively, a pre-established model may calculate the required duration based on chamber parameters, including the gap between the plasma source (104) and the chuck (134), neutral density, temperature, and the distance between the etch front and the substrate's surface.

In other implementations, the duration for the surface modification step, is determined based on tests conducted during the ALE process recipe development phase. These tests, including but not limited to DOE, ascertain the optimized duration as a function of the distance.

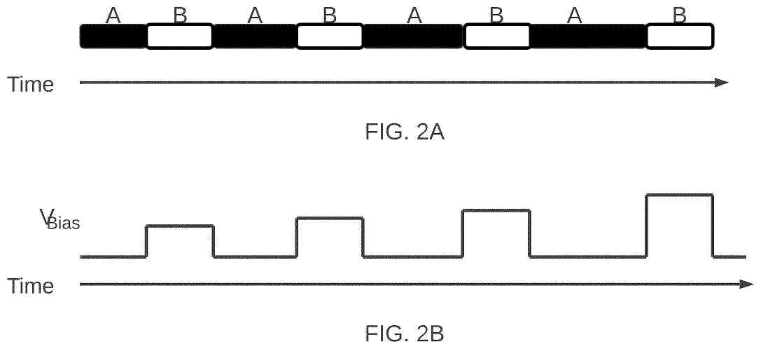

FIG. 2A schematically illustrates an exemplary implementation of the ALE process. In this depiction, the surface modification step is marked as “A”, and the sputtering step as “B”. Notably, the duration of “A” is progressively increased in correlation with the ALE cycle count.

During the sputtering step, it is crucial that enough ions reach the etch front to effectively remove the modified layer. It is recognized that in the art of HAR structure formation, the percentage of ions reaching the etch front diminishes as the etch front delves deeper into the substrate surface. This reduction, largely due to ion momentum angular distribution, results in more ions impacting the sidewalls rather than removing the modified layer at the etch front as the aspect ratio increases. To mitigate this issue, increasing the bias level to the chuck, thereby elevating ion energy, is a viable strategy. However, this approach must be balanced against the need to maintain selectivity to other surfaces, such as hard mask layers, which is a critical aspect of advanced semiconductor manufacturing.

FIG. 2B exemplarily demonstrates how, in some embodiments, the controller (140) progressively increases ion energy in tandem with the ALE cycle count. The controller (140) may determine the bias for each specific ALE cycle based on a pre-established model, considering chamber parameters like the gap between the plasma source (104) and the chuck (134), ion density, ion energy distribution, angular distribution of the ion momentum, and the distance between the etch front and the substrate surface.

In alternative implementations, the optimal bias level for a specific ALE cycle, particularly characterized by the distance, is ascertained through various tests conducted during the ALE process recipe development phase. These tests, including but not limited to DOE, are aimed at determining the optimized bias level relative to the distance between the etch front and the substrate surface.

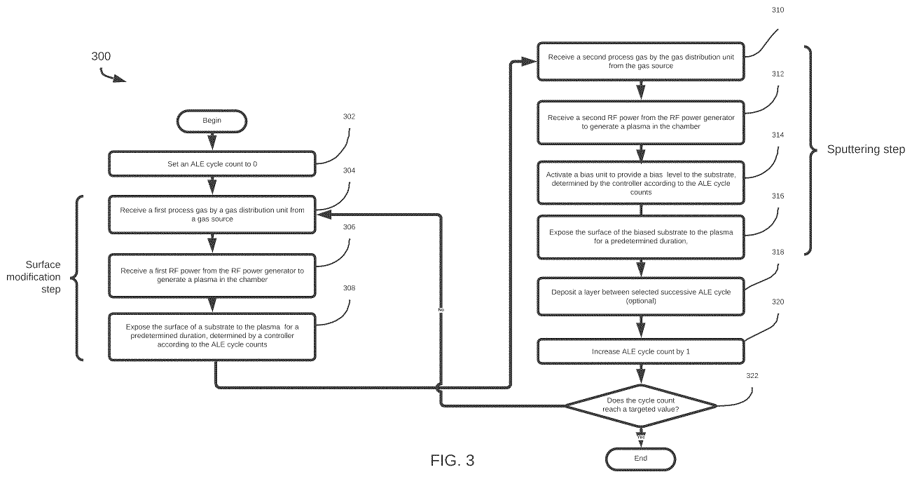

FIG. 3 outlines a comprehensive ALE process flow, labeled as process 300. The process initiates at step 302, where the ALE cycle count is set to zero by the controller (140). The surface modification step encompasses steps 304, 306, and 308. At step 304, the first process gas (111) is supplied to the gas distribution unit (108) from the gas source (110). Subsequently, at step 306, the plasma source (104) receives the first RF power from the RF power generator (106), generating a plasma within the chamber (102). At step 308, the surface of the substrate (136) is exposed to the plasma for a controller-determined, cycle-specific duration. This exposure duration may be progressively increased as the ALE cycle count ascends.

The sputtering step includes steps 310, 312, 314, and 316. At step 310, the second process gas (113) is received by the gas distribution unit (108). Following this, at step 312, the plasma source (104) is powered with the second RF power to generate plasma in the chamber (102). At step 314, the bias unit (138) is activated, accelerating ions towards the surface of the substrate (136). The controller (140) regulates the bias level based on the ALE cycle counts. In certain implementations, this bias level is progressively increased as the ALE cycle count is increased. Step 316 involves exposing the substrate to the plasma for a predetermined duration, allowing the accelerated ions to remove the modified layer. The duration of this sputtering step can either be constant throughout the ALE process or varied, such as by increasing in line with the ALE cycle count.

For HAR structure formation, step 318 optionally introduces a deposition step. This step involves depositing a layer to protect the structure's sidewalls from lateral etching, induced by the ion momentum's angular distribution. This deposition step, which could include a carbon layer, an oxide layer, silicon nitride layer, or a combination thereof, is not obligatory between every ALE cycle and may be inserted between selected successive ALE cycles.

At step 320, the ALE cycle count is incremented by one. Then, at step 322, the controller (140) evaluates the ALE cycle count. If the count reaches a targeted value, the ALE process concludes; otherwise, an additional ALE cycle will be conducted.

It should be noted that some steps are not listed in the process for simplicity. For example, the first process gas is removed from the chamber before the sputtering step is started and vice versa.

The embodiments described herein are exemplary and represent a fraction of the variations encompassed within the scope of the inventive concept. In some implementations, other process parameters as specified by a process recipe are changed by the controller (140) as the ALE cycle count is increased. The implementations may involve variations in the first and second RF power levels, other RF power parameters (like frequency or frequency combinations), gas compositions, chamber pressure, or chuck temperature, all potentially varying in accordance with the ALE cycle count.

In certain implementations of the ALE process, adjustments to the first and second RF powers are executed in accordance with the ALE cycle count. This approach allows for dynamic control of the plasma characteristics, optimizing the etching process for different stages of the ALE cycles.

Additionally, other parameters related to the RF power are subject to modification as a function of the ALE cycle count. For instance, this includes varying the frequencies or combinations thereof used for the RF power, both for the plasma source and the bias unit. Such adjustments enable fine-tuning of the plasma's properties, tailoring them to the evolving requirements of the etching process as it progresses through successive cycles.

In some other embodiments, the first and second process gases employed in the ALE cycles are composed of mixed process gases. The composition of these process gases can be varied in relation to the ALE cycle count. This variation in process gas composition allows for the adaptation of the etching and deposition characteristics to the specific needs of different stages within the ALE process.

Furthermore, the pressure within the chamber is another variable that can be dynamically adjusted according to the ALE cycle count. Modulating the chamber pressure offers another degree of control over the etching environment, affecting factors such as ion density and mean free path of particles within the chamber.

Still furthermore, the temperature of the chuck is also subject to adjustment based on the ALE cycle count. Adjusting the chuck temperature can influence the thermal properties of the substrate, which in turn can impact the etching rate and uniformity, as well as the deposition characteristics.

Lastly, the deposition conditions including and not limited to chamber pressure, chuck temperature, deposition duration, gas flow rates may also be changed as a function of the ALE cycle counts.

Each of these implementation variations enhances the versatility and efficiency of the ALE process, enabling it to be tailored to a wide range of specific etching scenarios. The ability to modify these parameters in relation to the ALE cycle count provides a sophisticated level of control, crucial for advanced semiconductor manufacturing processes.

1. A method of performing an ALE process in a process system comprising:
a. updating ALE cycle count by a controller, wherein the count is set as zero before starting an ALE process;
b. operating the process system in a surface modification step by the controller, comprising:
I. receiving a first process gas by a gas distribution unit from a gas source;
II. receiving a first RF power by a plasma source from an RF power generator to generate a plasma in a chamber;
III. exposing a surface of a substrate to the plasma for a predetermined duration, wherein the duration is determined by the controller according to the ALE cycle count;
c. operating the process system in a sputtering step by the controller, comprising:
I. receiving a second process gas by the gas distribution unit from the gas source;
II. receiving a second RF power by the plasma source from the RF power generator to generate a plasma in the chamber;
III. activating a bias unit to provide a bias to the substrate, wherein the bias level is determined by the controller according to the ALE cycle count;
IV. exposing the surface of the biased substrate to the plasma for a predetermined duration; and
d. repeating steps a to c until the ALE cycle count reaches a targeted value.

2. The method of claim 1, wherein the method further includes a step of depositing a layer on the substrate between selected successive ALE cycles.

3. The method of claim 2, wherein process parameters at the step of the depositing are changed by the controller according to the ALE cycle count.

4. The method of claim 1, wherein the predetermined duration is determined based on a pre-established model.

5. The method of claim 1, wherein the predetermined duration is determined based on prior tests.

6. The method of claim 1, wherein the bias level is determined based on a pre-established model.

7. The method of claim 1, wherein the bias level is determined based on prior tests.

8. The method of claim 1, wherein the bias unit further includes a tailored waveform generator.

9. The method of claim 1, wherein the bias unit further includes an RF power generator.

10. The method of claim 1, wherein process parameters specified by a process recipe, other than the predetermined duration, at the surface modification step are changed by the controller according to the ALE cycle count.

11. The method of claim 1, wherein process parameters specified by a process recipe, other than the bias level, in the sputtering step are changed by the controller according to the ALE cycle count.

12. A process system for performing an ALE process, comprising:
a. a chamber maintaining an interior space for a vacuum environment;
b. a plasma source coupled to an RF power generator configured to generate plasma in the chamber;
c. a bias unit operatively connected to a chuck for supporting a substrate;
d. a gas distribution unit configured to receive process gases from a gas source and distribute the received process gases to the chamber; and
e. a controller configured to operate the process system in steps including a surface modification step and a sputtering step sequentially, wherein in the surface modification step, the controller determines the duration of the step according to an ALE cycle count, and wherein in the sputtering step, the controller determines the bias level from the bias unit according to the ALE cycle count.

13. The process system of claim 12, wherein the controller is further configured to progressively increase the duration for the surface modification step as the ALE cycle count is increased.

14. The process system of claim 12, wherein the controller is further configured to determine the duration based on a pre-established model.

15. The process system of claim 12, wherein the controller is further configured to determine the duration based on prior tests.

16. The process system of claim 12, wherein the controller is further configured to progressively increase the bias level as the ALE cycle count is increased.

17. The process system of claim 12, wherein the controller is further configured to determine the bias level based on a pre-established model.

18. The process system of claim 12, wherein the controller is further configured to determine the bias level based on prior tests.

19. The process system of claim 12, wherein the controller is further configured to enable depositing a layer between selected successive ALE cycles.

20. The process system of claim 19, wherein selected process parameters specified in a process recipe are changed by the controller according to the ALE cycle counts.
